(19) United States
(12) Patent Application Publication
(10) Pub. No.: US 2025/0008826 A1
(43) Pub. Date: Jan. 2, 2025

(54) DISPLAY DEVICE AND METHOD OF MANUFACTURING DISPLAY DEVICE

(71) Applicant: Samsung Display Co., LTD., Yongin-si (KR)

(72) Inventors: Jin A SEO, Yongin-si (KR); Su Jeong KIM, Yongin-si (KR); Yun Ho LEE, Yongin-si (KR); Eun Bee LEE, Yongin-si (KR)

(21) Appl. No.: 18/422,513

(22) Filed: Jan. 25, 2024

(30) Foreign Application Priority Data
Jun. 27, 2023 (KR) 10-2023-0082962

(51) Int. Cl. H10K 59/80; H10K 59/131; H10K 102/00

(52) U.S. Cl. CPC H10K 59/8792; H10K 59/131; H10K 59/873; H10K 59/878; H10K 2102/351

(57) ABSTRACT

A display device includes sub-pixels corresponding to sub-pixel areas. Each of the sub-pixels includes a display unit including a light-emitting layer which emits light, and a reflection control layer disposed over the sub-pixel areas on the display unit, where the reflection control layer selectively absorbs light in a wavelength band. The reflection control layer includes a first layer and a second layer disposed on the first layer, where the second layer has a thickness less than a thickness of the first layer. The second layer includes a liquid repellent material.

This application claims priority to Korean patent application No. 10-2023-0082962, filed on Jun. 27, 2023, and all the benefits accruing therefrom under 35 U.S.C. § 119, the content of which in its entirety is herein incorporated by reference.

### BACKGROUND

### 1. Field

The disclosure relates to a display device and a method of manufacturing the display device.

### 2. Description of the Related Art

As information technology is developed, importance of a display device, which is a connection medium between a user and information, has been highlighted, and thus research on an additional structure for improving display quality is being actively conducted.

A structure formed in the display device is desired to secure an effect of improving display quality, implement an intended technical effect during a sufficient period, and secure structural reliability.

### SUMMARY

An embodiment of the disclosure is to provide a display device and a method of manufacturing the display device having improved display quality.

An embodiment of the disclosure is to provide a display device and a method of manufacturing the display device configured to secure reliability in quality by improving structural stability.

According to an embodiment of the disclosure, a display device includes sub-pixels corresponding to sub-pixel areas. In such an embodiment, each of the sub-pixels may include a display unit including a light-emitting layer which emits light, and a reflection control layer disposed on the sub-pixel areas on the display unit, wherein the reflection control layer selectively absorbs light in a wavelength band. In such an embodiment, the reflection control layer includes a first layer and a second layer disposed on the first layer, where the second layer has a thickness less than that of the first layer, and the second layer includes a liquid repellent material.

According to an embodiment, the reflection control layer may absorb light in a non-emission wavelength band different from a wavelength band of light emitted from the light-emitting layer. In such an embodiment, the non-emission wavelength band may include a first non-emission wavelength band and a second non-emission wavelength band. In such an embodiment, the wavelength band of the light emitted from the light-emitting layer may include a first wavelength band, a second wavelength band, and a third wavelength band. In such an embodiment, the first non-emission wavelength band may include a wavelength band between the third wavelength band and the second wavelength band, and the second non-emission wavelength band may include a wavelength band between the second wavelength band and the first wavelength band.

According to an embodiment, the first non-emission wavelength band may include at least a partial band of 460 nm to 520 nm, and the second non-emission wavelength band may include at least a partial band of 560 nm to 620 nm. In such an embodiment, the first wavelength band may be a red wavelength band, the second wavelength band may be a green wavelength band, and the third wavelength band may be a blue wavelength band.

According to an embodiment, the reflection control layer may include a dye, a pigment, or a combination thereof.

According to an embodiment, the reflection control layer may include at least one selected from an oxazine-based compound, a cyanine-based compound, a tetraazoporfin-based compound, and a squarylium-based compound.

According to an embodiment, the display unit may include a light emitting element including a first electrode, a second electrode, and the light-emitting layer electrically connected between the first electrode and the second electrode, and a low reflection inorganic layer disposed on the light emitting element.

According to an embodiment, the second electrode may be disposed on the light-emitting layer. In such an embodiment, light reflected by the low reflection inorganic layer and light reflected by the second electrode may destructively interfere with each other.

According to an embodiment, the display device may further include a light blocking layer disposed between the display unit and the reflection control layer, where an opening may be defined in the light blocking layer. In such an embodiment, the opening and the sub-pixel areas may overlap each other in a plan view, and the reflection control layer may contact the light blocking layer.

According to an embodiment, the light blocking layer may contact the first layer and spaced apart from the second layer.

According to an embodiment, the liquid repellent material may have liquid repellency greater than a liquid repellency of a dye, a pigment, or a combination thereof included in the reflection control layer.

According to an embodiment, the liquid repellent material may have a surface energy greater than a surface energy of a dye, a pigment, or a combination thereof included in the reflection control layer.

According to an embodiment, the second layer may have a structure of a film shape on the first layer.

According to an embodiment, the second layer may have a hardness greater than a hardness of the first layer.

According to an embodiment, in the second layer, the liquid repellent material may be included at a concentration of 500 ppm or less.

According to an embodiment, the display device may further include a protective film disposed on the reflection control layer. In such an embodiment, the protective film may contact the second layer and is spaced apart from the first layer.

According to an embodiment of the disclosure, a display device includes a display unit, and a reflection control layer disposed on the display unit, where the reflection control layer selectively absorbs light in a wavelength band, and includes a first surface facing the display unit and a second surface opposite to the first surface. In such an embodiment, the reflection control layer may include a first layer adjacent to the first surface and a second layer disposed on the first layer and adjacent to the second surface, and the second layer may have a hardness greater than a hardness of the first layer.

According to an embodiment of the disclosure, a method of manufacturing a display device includes providing a display unit, and providing a base reflection control layer including a dye and a liquid repellent material on the display unit. In such an embodiment, the base reflection control layer includes a first surface adjacent to the display unit and a second surface opposite to the first surface, and in the providing the base reflection control layer on the display unit, the liquid repellent material is moved to be adjacent to the second surface.

According to an embodiment, in the providing the base reflection control layer on the display unit, a reflection control layer including a first layer and a second layer disposed on the first layer and including the liquid repellent material is provided based on the base reflection control layer. In such an embodiment, the method may further include curing the reflection control layer, and after the curing, the second layer may have a hardness greater than a hardness of the first layer.

According to an embodiment, in the providing the base reflection control layer on the display unit, the second surface of the base reflection control layer may be exposed.

According to an embodiment, the method may further include disposing a protective film on the reflection control layer, where the protective film may be spaced apart from the first layer and may physically contact the second layer.

According to an embodiment of the disclosure, a display device and a method of manufacturing the display device having improved display quality may be provided.

According to an embodiment of the disclosure, a display device and a method of manufacturing the display device configured to secure reliability in quality by improving structural stability may be provided.

### BRIEF DESCRIPTION OF THE DRAWINGS

The above and other features of the disclosure will become more apparent by describing in further detail embodiments thereof with reference to the accompanying drawings, in which:

FIG. 1 is a diagram illustrating a display device according to an embodiment;

FIG. 2 is a schematic cross-sectional view illustrating a stack structure of a display device according to an embodiment;

FIG. 3 is a schematic cross-sectional view illustrating a display unit according to an embodiment;

FIG. 4 is a schematic cross-sectional view illustrating a sensor unit according to an embodiment;

FIG. 5 is a schematic cross-sectional view illustrating a display device according to an embodiment;

FIG. 6 is a schematic cross-sectional view illustrating an outer unit according to an embodiment; and

FIGS. 7 to 9 are schematic cross-sectional views for each process step illustrating a method of manufacturing a display device according to an embodiment.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

Terms of “first”, “second”, and the like may be used to describe various components, but the components should not be limited by the terms. The terms are used only for the purpose of distinguishing one component from another component. For example, without departing from the scope of the disclosure, a first component may be referred to as a second component, and similarly, a second component may also be referred to as a first component.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

In addition, a case where a portion of a layer, a layer, an area, a plate, or the like is referred to as being “on” another portion, it includes not only a case where the portion is “directly on” another portion, but also a case where there is further another portion between the portion and another portion. In addition, in the present specification, when a portion of a layer, a layer, an area, a plate, or the like is formed on another portion, a forming direction is not limited to an upper direction but includes forming the portion on a side surface or in a lower direction. On the contrary, when a portion of a layer, a layer, an area, a plate, or the like is formed “under” another portion, this includes not only a case where the portion is “directly beneath” another portion but also a case where there is further another portion between the portion and another portion.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within +30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, a display device and a method of manufacturing the display device according to an embodiment will be described with reference to the accompanying drawings.

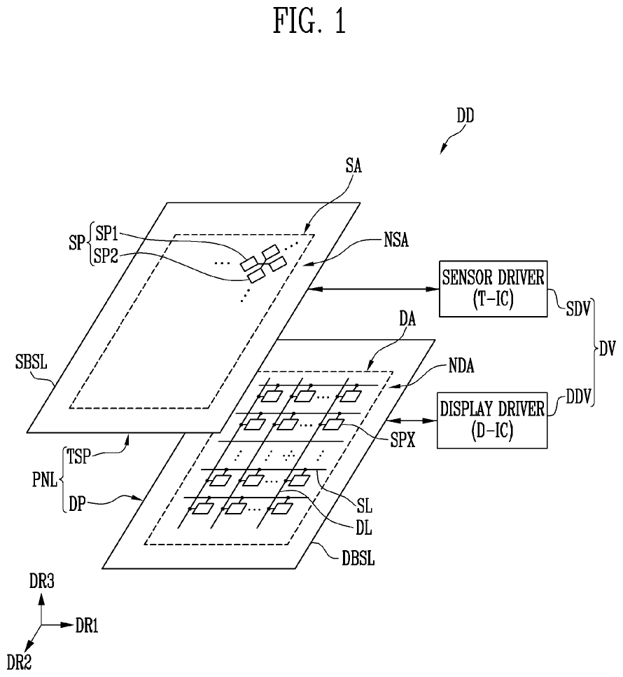

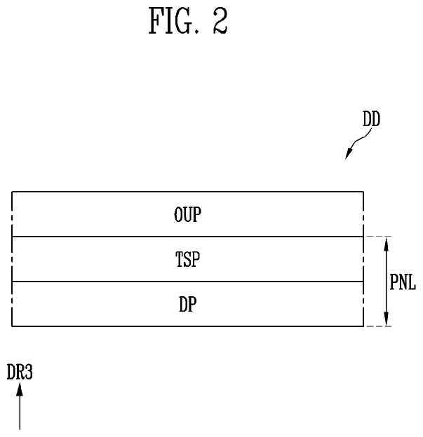

FIG. 1 is a diagram illustrating a display device according to an embodiment. FIG. 2 is a schematic cross-sectional view illustrating a stack structure of a display device according to an embodiment.

Referring to FIGS. 1 and 2, an embodiment of the display device DD is configured to provide (or emit) light. The display device DD may include a panel PNL and a driving circuit unit DV for driving the panel PNL. The display device DD may further include an outer unit OUP.

The panel PNL may include a display unit DP for displaying an image and a sensor unit TSP configured to sense a user input (for example, a touch input). The display unit DP may be referred to as a display panel, display part, or display layer. The sensor unit TSP may be referred to as a sensing panel, a touch sensor, sensing part, or sensing layer.

The panel PNL may include sub-pixels SPX and sensing electrodes SP. According to an embodiment, the sub-pixels SPX may display an image in a display frame period unit. The sensing electrodes SP may sense an input (for example, a touch input) of a user in a sensing frame period unit. A sensing frame period and a display frame period may be independent of each other or may be different from (e.g., not be temporally overlap) each other. The sensing frame period and the display frame period may be synchronized or asynchronous with each other.

The sensor unit TSP including the sensing electrodes SP may obtain information on the touch input of the user. According to an embodiment (for example, a mutual capacitance method), the sensing electrodes SP may include a first sensing electrode SP1 that provides a first sensing signal and a second sensing electrode SP2 that provides a second sensing signal. According to an embodiment, the first sensing electrode SP1 may be a Tx (transmitter) pattern electrode, and the second sensing electrode SP2 may be an Rx (receiver) pattern electrode. According to an embodiment, the information on the touch input (or a touch event) may mean information including a position or the like of a touch that the user wants to provide.

However, the disclosure is not limited thereto. For example, according to an alternative embodiment, the sensing electrodes SP may be configured of one type of sensing electrodes without distinction between the first sensing electrode SP1 and the second sensing electrode SP2 (for example, a self-capacitance method).

The driving circuit unit DV may include a display driver DDV for driving the display unit DP and a sensor driver SDV for driving the sensor unit TSP.

The display unit DP may include a display base layer DBSL and the sub-pixels SPX provided on the display base layer DBSL. The sub-pixels SPX may be disposed in a display area DA. The sub-pixels SPX may form or collectively define a pixel (or a pixel unit).

The display base layer DBSL (or the display device DD) may include the display area DA on which an image is displayed and a non-display area NDA outside the display area DA. According to an embodiment, the display area DA may be disposed in a central area of the display unit DP, and the non-display area NDA may be disposed adjacent to a periphery of the display area DA.

The display base layer DBSL may be a base substrate or a base member for supporting the display device DD. The base layer may be a rigid substrate including a glass material. Alternatively, the base layer may be a flexible substrate of which bending, folding, rolling, or the like is possible. In such an embodiment, the base layer may include an insulating material such as a polymer resin such as polyimide. However, the disclosure is not particularly limited thereto.

Scan lines SL and data lines DL, and the sub-pixels SPX connected to the scan lines SL and the data lines DL are disposed in the display area DA. The sub-pixels SPX may be configured to be selected by a scan signal of a turn-on level supplied from the scan lines SL, receive a data signal from the data lines DL, and emit light of a luminance corresponding to the data signal. Accordingly, an image corresponding to the data signal is displayed in the display area DA. However, in the disclosure, a structure, a driving method, or the like of the sub-pixels SPX are not particularly limited.

Various lines and/or built-in circuit units connected to the sub-pixels SPX of the display area NDA may be disposed in the non-display area NDA. In an embodiment, for example, a plurality of lines for supplying various power and control signals to the display area DA may be disposed in the non-display area NDA.

The display unit DP may output visual information (for example, an image). According to an embodiment, a type/kind of the display unit DP is not particularly limited. In an embodiment, for example, the display unit DP may be implemented as a self-emission type display panel such as an organic light emitting display panel. In an embodiment, where the display unit DP is implemented as a self-emission type, each pixel is not limited to a case in which only an organic light emitting element is included. In an embodiment, for example, a light emitting element of each pixel may be formed of an organic light emitting diode, an inorganic light emitting diode, a quantum dot/well light emitting diode, or the like.

Hereinafter, for convenience of description, embodiments in which the display unit DP is implemented as an organic light emitting display panel will be described in detail.

The sensor unit TSP includes a sensor base layer SBSL and a plurality of sensing electrodes SP provided or formed on the sensor base layer SBSL. The sensing electrodes SP may be disposed in a sensing area SA on the sensor base layer SBSL.

The sensor base layer SBSL (or the display device DD) may include the sensing area SA where a touch input or the like may be sensed, and a non-sensing area NSA around the sensing area SA. According to an embodiment, the sensing area SA may be disposed to overlap at least one area of the display area DA. In an embodiment, for example, the sensing area SA may be set as an area corresponding to the display area DA (for example, an area overlapping the display area DA), and the non-sensing area NSA may be set as an area corresponding to the non-display area NDA (for example, an area overlapping the non-display area NDA). In such an embodiment, when the touch input or the like is provided on the display area DA, the touch input may be detected through the sensor unit TSP.

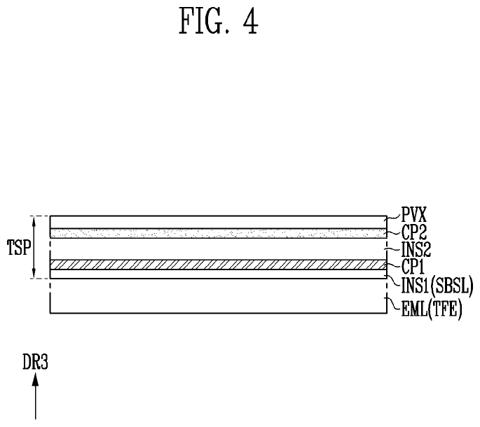

The sensor base layer SBSL may include one or more insulating layers (for example, a first insulating layer INS1 (refer to FIG. 4)). In an embodiment, for example, the first insulating layer INS1 for forming the sensor base layer SBSL may be disposed on the display unit DP to provide a base for forming the sensing electrodes SP. However, an example for forming the sensor base layer SBSL is not particularly limited.

The sensing area SA is set as an area configured to respond to the touch input (that is, an active area of a sensor). In an embodiment, the sensing electrodes SP for sensing the touch input or the like may be disposed in the sensing area SA.

The sensor unit TSP may obtain information on an input provided from the user. The sensor unit TSP may recognize the touch input. The sensor unit TSP may recognize the touch input using a capacitive sensing method. The sensor unit TSP may sense the touch input using a mutual capacitance method or may sense the touch input using a self-capacitance method.

According to an embodiment, each of the first sensing electrodes SP1 may extend in a first direction DR1. The first sensing electrodes SP1 may be arranged in a second direction DR2. The second direction DR2 may be different from the first direction DR1. In an embodiment, for example, the second direction DR2 may be a direction perpendicular to the first direction DR1. Each of the first sensing electrodes SP1 may have a form in which first cells of a relatively large area and first bridge electrodes of a relatively small area are connected to each other. The first sensing electrodes SP1 may generally have a diamond shape. However, a shape of the first sensing electrodes SP1 is not particularly limited.

According to an embodiment, each of the second sensing electrodes SP2 may extend in the second direction DR2. The second sensing electrodes SP2 may be arranged in the first direction DR1. Each of the second sensing electrodes SP2 may have a form in which second cells of a relatively large area and second bridge electrodes of a relatively small area are connected to each other. The second sensing electrodes SP2 may generally have a diamond shape. However, a shape of the second sensing electrodes SP2 is not particularly limited.

According to an embodiment, the first sensing electrodes SP1 and the second sensing electrodes SP2 may have a same (for example, substantially a same) shape as each other. In an embodiment, for example, the first sensing electrodes SP1 which are Tx patterns and the second sensing electrodes SP2 which are Rx patterns may have substantially a same shape, and thus sensing performance of the touch event may be uniformly set within the sensing area SA.

In an embodiment, sensing lines for electrically connecting the sensing electrodes SP to the sensor driver SDV or the like may be disposed in the non-sensing area NSA of the sensor unit TSP.

The driving circuit unit DV may include the display driver DDV for driving the display unit DP and the sensor driver SDV for driving the sensor unit TSP.

The display driver DDV is configured to be electrically connected to the display unit DP to drive the sub-pixels SPX. The sensor driver SDV is configured to be electrically connected to the sensor unit TSP to drive the sensor unit TSP.

The outer unit OUP may be disposed substantially above the display device DD based on a thickness direction (for example, a third direction DR3) of the display base layer DBSL. The outer unit OUP may be disposed on the sensor unit TSP. Light provided from the display unit DP may pass through the outer unit OUP and may be output to an outside. The outer unit OUP may be referred as an outer part, an outer layer, or an upper layer.

The outer unit OUP may include a light blocking layer BM to improve visibility of the display device DD. In an embodiment, for example, the light blocking layer BM may be disposed to overlap the first sensing electrodes SP1 and the second sensing electrodes SP2 forming the sensor unit TSP, to prevent visibility from being lowered by the first sensing electrodes SP1 and the second sensing electrodes SP2.

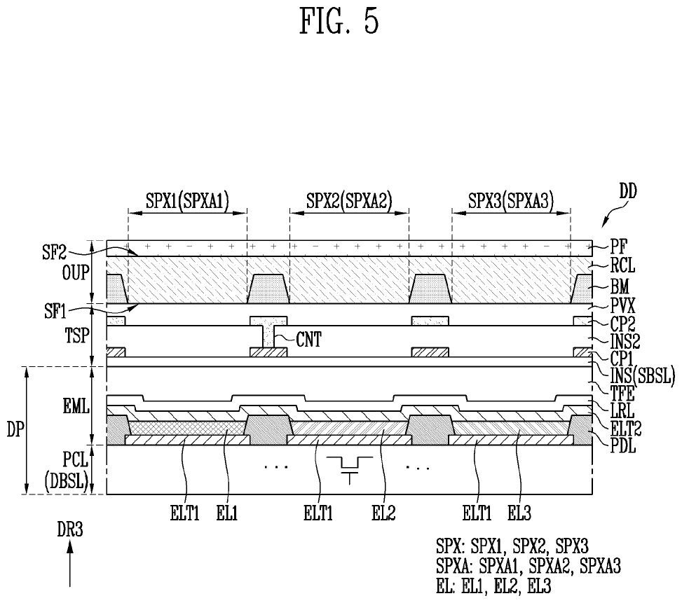

The outer unit OUP may further include a reflection control layer RCL (refer to FIG. 5) capable of improving display quality. As the reflection control layer RCL according to an embodiment is disposed, display quality of the display device DD may be improved with secured reliability. A detailed content regarding this will be described later.

According to an embodiment, the outer unit OUP may protect internal configurations of the display device DD from an external influence. In an embodiment, for example, the outer unit OUP may further include a protective film PF (refer to FIG. 5) configured to transmit light.

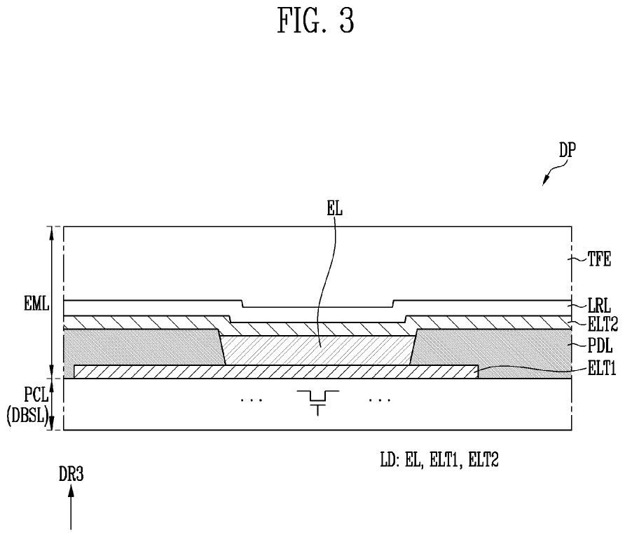

Next, with reference to FIG. 3, an embodiment of the display unit DP will be described. FIG. 3 is a schematic cross-sectional view illustrating a display unit according to an embodiment.

Referring to FIG. 3, an embodiment of the display unit DP may include a pixel-circuit layer PCL and a light-emitting-element layer EML.

The pixel-circuit layer PCL may include a pixel circuit for driving light emitting elements LD. The pixel-circuit layer PCL may include the display base layer DBSL, conductive layers constituting pixel circuits, and insulating layers disposed between the conductive layers.

The pixel circuit may include a driving transistor. The pixel circuit may include a thin film transistor. The pixel circuit may be electrically connected to the light emitting elements LD to provide an electrical signal for the light emitting elements LD to emit light.

The light-emitting-element layer EML may be disposed on the pixel-circuit layer PCL. According to an embodiment, the light-emitting-element layer EML may include the light emitting element LD, a pixel defining layer PDL, a low reflection inorganic layer LRL, and an encapsulation layer TFE.

The light emitting element LD may be disposed on the pixel-circuit layer PCL. According to an embodiment, the light emitting element LD may include a first electrode ELT1, a light-emitting layer EL, and a second electrode ELT2. According to an embodiment, the light-emitting layer EL may be disposed in an area defined by (or in an opening defined through) the pixel defining layer PDL. The pixel defining layer PDL may be adjacent to a periphery of the light-emitting layer EL. A surface of the light-emitting layer EL may be electrically connected to the first electrode ELT1, and another surface of the light-emitting layer EL may be electrically connected to the second electrode ELT2.

The first electrode ELT1 may be an anode electrode for the light-emitting layer EL, and the second electrode ELT2 may be a common electrode (or a cathode electrode) for the light-emitting layer EL. According to an embodiment, the first electrode ELT1 and the second electrode ELT2 may include a conductive material. In an embodiment, for example, the first electrode ELT1 may include a conductive material having a reflective property, and the second electrode ELT2 may include a transparent conductive material. However, the disclosure is not limited thereto.

The light-emitting layer EL may have a multilayer thin film structure including a light generation layer. The light-emitting layer EL may include a hole injection layer for injecting a hole, a hole transport layer having an excellent hole transport property and for increasing a chance of recombination of a hole and an electron by suppressing a movement of an electron that is not combined in the light generation layer, the light generation layer for emitting light by the recombination of the injected electron and hole, a hole blocking layer for suppressing a movement of a hole that is not combined in the light generation layer, an electron transport layer for smoothly transporting the electron to the light generation layer, and an electron injection layer for injecting the electron. The light-emitting layer EL may emit light based on an electrical signal provided from the first electrode ELT1 and the second electrode ELT2.

According to an embodiment, the light-emitting layer EL may emit light in a wavelength band. In an embodiment, for example, the light-emitting layer EL may include a first light-emitting layer EL1 (refer to FIG. 5) configured to emit light of a first color in a first wavelength band, a second light-emitting layer EL2 (refer to FIG. 5) configured to emit light of a second color in a second wavelength band, and a third light-emitting layer EL3 (refer to FIG. 5) configured to emit light of a third color in a third wavelength band.

The first light-emitting layer EL1 may form a first light emitting element that emits the light of the first color, the second light-emitting layer EL2 may form a second light emitting element that emits the light of the second color, and the third light-emitting layer EL3 may form a third light emitting element that emits the light of the third color.

The first color may be red. In an embodiment, for example, the first wavelength band may be a wavelength band of about 600 nanometers (nm) to 750 nm. The second color may be green. In an embodiment, for example, the second wavelength band may be a wavelength band of about 480 nm to 560 nm. The third color may be blue. In an embodiment, for example, the third wavelength band may be a wavelength band of about 370 nm to 460 nm.

According to an embodiment, the light-emitting layer EL may not substantially emit light in a non-emission wavelength band. In the disclosure, the non-emission wavelength band may be a wavelength band including a wavelength that at least does not partially overlap a wavelength band of light emitted from the light-emitting layer EL.

According to an embodiment, the non-emission wavelength band may not overlap the wavelength band of the light emitted from the light-emitting layer EL. In an embodiment, for example, the non-emission wavelength band may not overlap the first wavelength band. The non-emission wavelength band may not overlap the second wavelength band. The non-emission wavelength band may not overlap the third wavelength band.

According to an embodiment, the non-emission wavelength band may include a first non-emission wavelength band and a second non-emission wavelength band. The second non-emission wavelength band may be a wavelength band greater than the first non-emission wavelength band.

In an embodiment, for example, the first non-emission wavelength band may include a wavelength band between the third wavelength band and the second wavelength band. The first non-emission wavelength band may include a wavelength band between a peak wavelength of the third wavelength band and a peak wavelength of the second peak wavelength band. The second non-emission wavelength band may include a wavelength band between the second wavelength band and the first wavelength band. The first non-emission wavelength band may include a wavelength band between a peak wavelength of the second wavelength band and a peak wavelength of the first peak wavelength band.

According to an embodiment, the first non-emission wavelength band may be a wavelength band of about 460 nm to about 520 nm. Alternatively, according to an embodiment, the first non-emission wavelength band may be a wavelength band of about 490 nm to about 505 nm. According to an embodiment, the second non-emission wavelength band may be a wavelength band of about 560 nm to about 620 nm. Alternatively, according to an embodiment, the second non-emission wavelength band may be a wavelength band of about 585 nm to about 600 nm. However, the disclosure is not necessarily limited thereto.

According to an embodiment, the reflection control layer RCL configured to selectively absorb light in the non-emission wavelength band of the light-emitting layer EL may be disposed, and thus a reflectance and a color sense of the display device DD may be improved. A detailed content regarding this will be described later.

The pixel defining layer PDL may be disposed on the pixel-circuit layer PCL to define a position where the light-emitting layer EL is disposed. The pixel defining layer PDL may include an organic material. According to an embodiment, the pixel defining layer PDL may include at least one selected from acrylic resin, epoxy resin, phenol resin, polyamide resin, and polyimide resin. However, the disclosure is not limited thereto. The pixel defining layer PDL may include an inorganic material.

The low reflection inorganic layer LRL may be disposed on the light emitting element LD (for example, the second electrode ELT2). The low reflection inorganic layer LRL may be disposed between the encapsulation layer TFE and the light emitting element LD.

The low reflection inorganic layer LRL may include an inorganic material. In an embodiment, for example, the low reflection inorganic layer LRL may include a metal or a metal compound. In an embodiment, for example, the metal may include at least one selected from aluminum (AI), silver (Ag), magnesium (Mg), chromium (Cr), titanium (Ti), nickel (Ni), gold (Au), tantalum (Ta), copper (Cu), calcium (Ca), cobalt (Co), iron (Fe), molybdenum (Mo), tungsten (W), platinum (Pt), bismuth (Bi), and ytterbium (Yb). In an embodiment, for example, the metal compound may include at least one selected from silicon oxide (SiOx), titanium oxide (TiOx), zirconium oxide (ZrOx), tantalum oxide (TaxOy), hafnium oxide (HfOx), aluminum oxide (AlxOy,) zinc oxide (ZnOx), yttrium oxide (YxOy), beryllium oxide (BeOx), magnesium oxide (MgOx), lead oxide (PbOx), tungsten oxide (WOx), bismuth oxide (BiOx), silicon nitride (SiNx), lithium fluoride (LiFx), calcium fluoride (CaFx), magnesium fluoride (MgFx), and cadmium sulfide (CdSx). One or more of the above-described materials may be selected as the low reflection inorganic layer LRL in consideration of a refractive index and an absorption coefficient.

In an embodiment, the low reflection inorganic layer LRL may reflect light incident thereto. In such an embodiment, light reflected by the low reflection inorganic layer LRL and light reflected by a portion (for example, the second electrode ELT2) of the light emitting element LD may interfere destructively with each other. Accordingly, an external light reflectance of the display device DD may be reduced, and display quality and visibility of the display device DD may be improved.

The encapsulation layer TFE may be disposed on the low reflection inorganic layer LRL. The encapsulation layer TFE may offset a step difference generated by the light emitting element LD, the low reflection inorganic layer LRL, and the pixel defining layer PDL. The encapsulation layer TFE may include a plurality of insulating layers covering the light emitting element LD. According to an embodiment, the encapsulation layer TFE may have a structure in which an inorganic layer and an organic layer are alternately stacked. According to an embodiment, the encapsulation layer TFE may be an encapsulation layer of a structure in which a first inorganic layer, an organic layer, and a second inorganic layer are sequentially stacked. According to an embodiment, the encapsulation layer TFE may be a thin film encapsulation layer.

Next, with reference to FIG. 4, a cross-sectional structure of the sensor unit TSP will be described.

FIG. 4 is a schematic cross-sectional view illustrating a sensor unit according to an embodiment.

According to an embodiment, the sensor unit TSP may be disposed on the light-emitting-element layer EML (or the encapsulation layer TFE). According to an embodiment, the sensor unit TSP may be directly disposed on the encapsulation layer TFE. The sensor unit TSP may include the first insulating layer INS1, a first conductive pattern layer CP1, a second insulating layer INS2, a second conductive pattern layer CP2, and a protective layer PVX.

According to an embodiment, the first conductive pattern layer CP1 and the second conductive pattern layer CP2 may be patterned at one position to form the sensing electrodes SP. In an embodiment, for example, a portion of each of the first conductive pattern layer CP1 and the second conductive pattern layer CP2 may configure the first sensing electrode SP1, and a portion of the second conductive pattern layer CP2 may configure the second sensing electrode SP2. However, the disclosure is not limited thereto.

The first insulating layer INS1 may be disposed on the encapsulation layer TFE. The first insulating layer INS1 may form the sensor base layer SBSL, and may provide area surface on which the first conductive pattern layer CP1, the second insulating layer INS2, the second conductive pattern layer CP2, and the protective layer PVX are disposed.

The first insulating layer INS1 may include an inorganic material. The inorganic material may include at least one selected from silicon nitride (SiNx), silicon oxide (SiOx), silicon oxynitride (SiOxNy), and aluminum oxide (AIOx). However, the disclosure is not limited thereto.

The first conductive pattern layer CP1 may be disposed on the first insulating layer INS1. The second conductive pattern layer CP2 may be disposed on the second insulating layer INS2. The first conductive pattern layer CP1 and the second conductive pattern layer CP2 may be spaced apart from each other with the second insulating layer INS2 interposed therebetween.

The first conductive pattern layer CP1 and the second conductive pattern layer CP2 may include a metal layer of a single layer or multiple layers. The first conductive pattern layer CP1 and the second conductive pattern layer CP2 may include at least one selected from various metal materials including gold (Au), silver (Ag), aluminum (Al), molybdenum (Mo), chromium (Cr), titanium (Ti), nickel (Ni), neodymium (Nd), copper (Cu), and platinum (Pt), or an alloy thereof. According to an embodiment, the first conductive pattern layer CP1 and the second conductive pattern layer CP2 may include at least one selected from various transparent conductive materials including one of a silver nanowire (AgNW), indium tin oxide (ITO), indium zinc oxide (IZO), indium gallium zinc oxide (IGZO), antimony zinc oxide (AZO), indium tin zinc oxide (ITZO), zinc oxide (ZnO), tin oxide (SnO2), carbon nano tube, and graphene.

The second insulating layer INS2 may be disposed on the first conductive pattern layer CP1. The second insulating layer INS2 may be interposed between the first conductive pattern layer CP1 and the second conductive pattern layer CP2. The protective layer PVX may be disposed on the second conductive pattern layer CP2.

The second insulating layer INS2 may include an organic material. The protective layer PVX may include an organic material. The organic material may include at least one selected from acrylic resin, methacrylic resin, polyisoprene, vinyl resin, epoxy resin, urethane resin, cellulose resin, siloxane resin, polyimide resin, polyamide resin, and perylene resin. However, the disclosure is not necessarily limited thereto. The second insulating layer INS2 and/or the protective layer PVX may include an inorganic material.

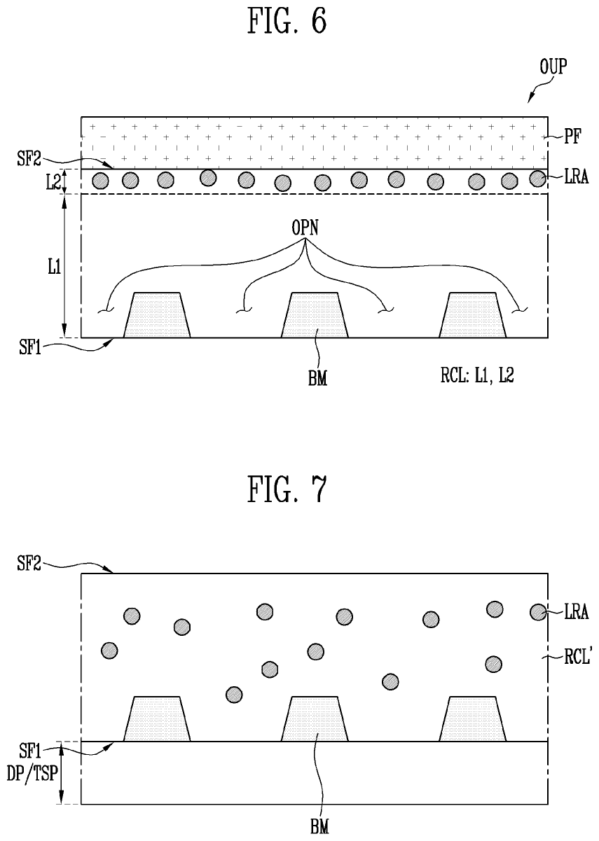

Next, with reference to FIGS. 5 and 6, the display device DD including the reflection control layer RCL according to an embodiment will be described.

FIG. 5 is a schematic cross-sectional view illustrating a display device according to an embodiment. FIG. 6 is a schematic cross-sectional view illustrating an outer unit according to an embodiment.

The display device DD according to an embodiment may include first to third light-emitting layers EL1, EL2, and EL3 emitting light of different colors.

In an embodiment, the display device DD may include sub-pixels SPX1, SPX2, and SPX3 each forming a sub-pixel area SPXA. The sub-pixel areas SPXA may include the first sub-pixel area SPXA1 where the light of the first color is emitted as an area formed by the first sub-pixel SPX1, the second sub-pixel area SPXA2 where the light of the second color is emitted as an area formed by the second sub-pixel SPX2, and the third sub-pixel area SPXA3 where the light of the third color is emitted as an area formed by the third sub-pixel SPX3.

According to an embodiment, the light of the first color of the first wavelength band may be emitted from the first sub-pixel area SPXA1. The light of the second color of the second wavelength band may be emitted from the second sub-pixel area SPXA2. The light of the third color of the third wavelength band may be emitted from the third sub-pixel area SPXA3.

According to an embodiment, the first conductive pattern layer CP1 and the second conductive pattern layer CP2 included in the sensor unit TSP may form the sensing electrodes SP.

According to an embodiment, a contact portion CNT may be formed in the second insulating layer INS2 included in the sensor unit TSP. The contact portion CNT may be disposed through (or disposed in a hole defined through) the second insulating layer INS2. According to an embodiment, at least a portion of the second conductive pattern layer CP2 may be electrically connected to the first conductive pattern layer CP1 through the contact portion CNT.

The outer unit OUP may be disposed on the sensor unit TSP and may include the light blocking layer BM, the reflection control layer RCL, and the protective film PF.

The light blocking layer BM may be disposed on the protective layer PVX. The light blocking layer BM may contact the protective layer PVX. The light blocking layer BM may contact the reflection control layer RCL. The light blocking layer BM may be disposed between the reflection control layer RCL and the display unit DP.

The light blocking layer BM may be disposed between adjacent sub-pixel areas SPXA. In an embodiment, for example, the light blocking layer BM may be disposed between the first sub-pixel area SPXA1 and the second sub-pixel area SPXA2, may be disposed between the second sub-pixel area SPXA2 and the third sub-pixel area SPXA3, and may be disposed between the first sub-pixel area SPXA1 and the third sub-pixel area SPXA3. According to an embodiment, an opening OPN (refer to FIG. 6) defined in the light blocking layer BM may overlap the sub-pixel area SPXA in a plan view or in the third direction DR3.

The light blocking layer BM may include a light absorbing material. The light absorbing material may include a colorant including at least one of carbon black and lactam black. However, the disclosure is not necessarily limited thereto, and the light absorbing material may be implemented with various materials. According to an embodiment, the light blocking layer BM may not include a light blocking structure formed by stacking two or more color filters.

The light blocking layer BM may overlap the first conductive pattern layer CP1 and the second conductive pattern layer CP2 in a plan view. Accordingly, the light blocking layer BM may effectively prevent visibility from being lowered by the first conductive pattern layer CP1 and the second conductive pattern layer CP2.

The reflection control layer RCL may be disposed outside the display unit DP based on a display direction (for example, the third direction DR3) of the display device DD. In an embodiment, for example, the reflection control layer RCL may be disposed on the sensor unit TSP (for example, the protective layer PVX).

The reflection control layer RCL may include a first surface SF1 and a second surface SF2. The first surface SF1 may be a lower surface of the reflection control layer RCL and may face the display unit DP. The second surface SF2 may be a surface opposite to the first surface SF1. The second surface SF2 may face the outside and may face the protective film PF.

The reflection control layer RCL may contact the light blocking layer BM. The reflection control layer RCL may contact the protective film PF. The reflection control layer RCL may contact an upper surface (for example, the protective layer PVX) of the sensor unit TSP.

The reflection control layer RCL may be disposed over the sub-pixels SPX. The reflection control layer RCL may be disposed over the sub-pixel areas SPXA. In an embodiment, for example, the reflection control layer RCL may be included in each of the first sub-pixel SPX1, the second sub-pixel SPX2, and the third sub-pixel SPX3. The reflection control layer RCL may be disposed over the first sub-pixel area SPXA1, the second sub-pixel area SPXA2, and the third sub-pixel area SPXA3. In an embodiment, for example, the reflection control layer RCL disposed in each of the first sub-pixel area SPXA1, the second sub-pixel area SPXA2, and the third sub-pixel area SPXA3 may be integrally formed with each other as a single unitary and indivisible part.

According to an embodiment, light emitted from the light-emitting layer EL may pass through the reflection control layer RCL and may be emitted to the outside. According to embodiment, the light emitted from the light-emitting layer EL may pass through the low reflection inorganic layer LRL and the reflection control layer RCL and may be output.

In an embodiment, for example, light emitted from the first light-emitting layer EL1 may pass through the reflection control layer RCL (or the low reflection inorganic layer LRL and the reflection control layer RCL) and may be emitted to the outside of the display device DD. Accordingly, the first sub-pixel area SPXA1 may be formed. Light emitted from the second light-emitting layer EL2 may pass through the reflection control layer RCL (or the low reflection inorganic layer LRL and the reflection control layer RCL) and may be emitted to the outside of the display device DD. Accordingly, the second sub-pixel area SPXA2 may be formed. Light emitted from the third light-emitting layer EL3 may pass through the reflection control layer RCL (or the low reflection inorganic layer LRL and the reflection control layer RCL) and may be emitted to the outside of the display device DD. Accordingly, the third sub-pixel area SPXA3 may be formed.

The reflection control layer RCL may selectively absorb light in a wavelength band. Accordingly, the reflection control layer RCL may control a reflectance of the display device DD, and thus may improve display quality of the display device DD.

The reflection control layer RCL may be configured to absorb at least a portion of light in the non-emission wavelength band for the light-emitting layer EL.

In an embodiment, for example, the reflection control layer RCL may absorb at least a portion of each of first light in the first non-emission wavelength band and second light in the second non-emission wavelength band.

According to an embodiment, the reflection control layer RCL may absorb at least a portion of light in a wavelength band of about 460 nm to about 520 nm, and may absorb at least a portion of light in a wavelength band of about 560 nm to about 620 nm. Alternatively, according to an embodiment, the reflection control layer RCL may absorb at least a portion of light in a wavelength band of about 490 nm to about 505 nm, and may absorb at least a portion of light in a wavelength band of about 585 nm to about 600 nm.

Accordingly, the reflection control layer RCL may absorb at least a portion of the light in the non-emission wavelength band for the light-emitting layer EL, and may improve display quality.

The reflection control layer RCL may include at least one selected from various materials. According to an embodiment, the reflection control layer RCL may include a dye, a pigment, or a combination thereof. In an embodiment, for example, the reflection control layer RCL may include at least one selected from various organic materials, and the reflection control layer RCL may include at least one selected from an oxazine-based compound, a cyanine-based compound, a tetraazoporfin-based compound, and a squarylium-based compound. However, the disclosure is not limited thereto.

According to an embodiment, the reflection control layer RCL may include a liquid repellent material LRA. The liquid repellent material LRA may be referred to as a “liquid repellent particle” or a “liquid repellent material”.

According to an embodiment, the reflection control layer RCL may include a layer (or a film portion) including the liquid repellent material LRA and a layer (or a body portion) that substantially does not include a liquid repellent material LRA or includes a liquid repellent material LRA of a concentration (for example, molarity) less than that of a liquid repellent material LRA included in an area adjacent to the second surface SF2.

In an embodiment, for example, the reflection control layer RCL may include a first layer L1 and a second layer L2. The first layer L1 may be a portion adjacent to the first surface SF1. The second layer L2 may be a portion adjacent to the second surface SF2.

The first layer L1 may contact the light blocking layer BM. According to an embodiment, at least a portion of the first layer L1 may be disposed in the opening OPN formed by the light blocking layer BM. The first layer L1 may overlap the opening OPN and the light blocking layer BM in a plan view.

The second layer L2 may be physically separated (or spaced apart) from the light blocking layer BM. According to an embodiment, the second layer L2 may overlap the opening OPN and the light blocking layer BM in a plan view.

The first layer L1 may have a thickness greater than that of the second layer L2. In an embodiment, for example, the first layer L1 may have a first thickness, and the second layer L2 may have a second thickness less than the first thickness. In an embodiment, for example, the second layer L2 may have a relatively thin film shape.

The first layer L1 substantially may not include the liquid repellent material LRA. In an embodiment, for example, the first layer L1 substantially may not include the liquid repellent material LRA in an area adjacent to the light blocking layer BM. According to an embodiment, the first layer L1 may include a small amount of liquid repellent material LRA in an area adjacent to the second layer L2.

The second layer L2 may include the liquid repellent material LRA. The liquid repellent material LRA may be distributed along an upper surface of the reflection control layer RCL. In an embodiment, for example, the liquid repellent material LRA may be relatively widely distributed to form a thin film structure. In an embodiment, for example, the liquid repellent material LRA may be disposed over the first sub-pixel area SPXA1, the second sub-pixel area SPXA2, and the third sub-pixel area SPXA3.

According to an embodiment, the second layer L2 may include the liquid repellent material LRA at a concentration in a range from 100 parts per million (ppm) to 500 ppm. If the liquid repellent material LRA is included at a concentration exceeding 500 ppm, the second layer L2 may not be sufficiently cured, and if the liquid repellent material LRA is contained at a concentration less than 100 ppm, a color transfer improvement effect may not appear because a liquid repellent component is insufficient. However, a numerical range according to the disclosure is not necessarily limited thereto.

According to an embodiment, the liquid repellent material LRA may include a material having a liquid repellency. According to an embodiment, the material having the liquid repellency may include a material generally having a hydrophobic property.

According to an embodiment, “liquid repellency” in the present specification may be defined as a contact angle of a droplet, which is formed by disposing an object material on a substrate or the like, with respect to the substrate of 50 degrees or greater.

According to an embodiment, the liquid repellent material LRA may include a polymer including a fluorine functional group. According to an embodiment, the liquid repellent material LRA may include a material represented by Chemical Formulas 1 to 3 below.

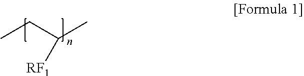

In Formula 1, R is an alkyl group having 100 or less carbon atoms, and n is a natural number equal to or greater than 100.

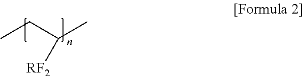

In Formula 2, R is an alkyl group having 100 or less carbon atoms, and n is a natural number equal to or greater than 100.

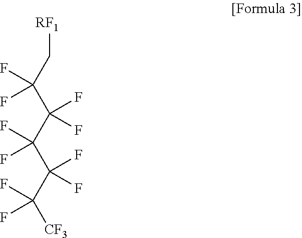

In Formula 3, R is an alkyl group having 100 or less carbon atoms.

Alternatively, according to an embodiment, the liquid repellent material LRA may include a material including a benzene ring. For example, the liquid repellent material LRA may include a material represented by Chemical Formula 4 below.

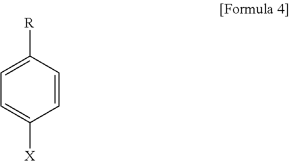

In Formula 4, R is an alkyl group having 100 or less carbon atoms, and X is a halogen element.

However, the disclosure is not limited thereto, and the liquid repellent material LRA may include a material represented by Chemical Formula 5 or Chemical Formula 6 as follows.

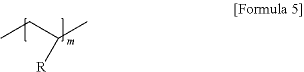

In Formula 5, R is an alkyl group having 100 or less carbon atoms, and m is a natural number equal to or less than 100.

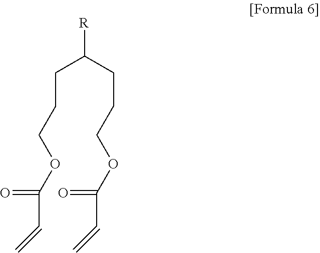

In Formula 6, R is an alkyl group having 100 or less carbon atoms.

According to an embodiment, the liquid repellent material LRA may have a surface energy greater than that of the dye, the pigment, or the combination thereof included in the reflection control layer RCL.

However, the disclosure is not necessarily limited thereto. In an embodiment, for example, the liquid repellent material LRA may include various materials having liquid repellency and/or surface energy greater than liquid repellency and/or surface energy of the dye, the pigment, or the combination thereof included in the reflection control layer RCL.

According to an embodiment, the second layer L2 including the liquid repellent material LRA may be disposed between the first layer L1 and the protective film PF. The liquid repellent material LRA may be directly adjacent to the protective film PF on one side of the second layer L2 that is not adjacent to the first layer L1. In an embodiment, for example, the second layer L2 may contact the protective film PF.

According to an embodiment, hardness of the first layer L1 may be less than hardness of the second layer L2. In an embodiment, for example, the second layer L2 may predominantly further include the liquid repellent material LRA, and the liquid repellent material LRA may be further cured in an area where the second layer L2 is formed. Accordingly, the second layer L2 may have hardness greater than that of the first layer L1 that does not include the liquid repellent material LRA or includes a predominantly relatively small amount of the liquid repellent material LRA.

According to an embodiment, the second layer L2 adjacent to the protective film PF may have high hardness and may limit the movement of the dye, the pigment, or the combination thereof included in the reflection control layer RCL. In an embodiment, for example, the dye, the pigment, or the combination thereof included in the reflection control layer RCL may be physically separated from the protective film PF by the second layer L2.

In such an embodiment, the dye, the pigment, or the combination thereof included in the reflection control layer RCL may be dyed to a layer directly adjacent to the reflection control layer RCL, such as the protective film PF, and thus a possibility that a color of the protective film PF or the like is changed (or distorted) may be reduced. As a result, since the reflection control layer RCL includes a layer in which the liquid repellent material LRA is distributed on an upper surface, the color change of the protective film PF or the like may be effectively prevented, and thus display quality of the display device DD may be improved.

In an embodiment, when the dye, the pigment, or the combination thereof included in the reflection control layer RCL is dyed to a layer directly adjacent to the reflection control layer RCL, the layer directly adjacent to the reflection control layer RCL, such as the protective film PF, may be contaminated, color quality of the display device DD is distorted over time, and light of an abnormal color is emitted. According to an embodiment, the layer directly adjacent to the reflection control layer RCL, such as the protective film PF, may be effectively prevented from being dyed, structural stability of the display device DD may be secured and reliability of quality may be improved.

In an embodiment, a structure of the reflection control layer RCL is not necessarily limited to the above-described example. In an alternative embodiment, for example, the reflection control layer RCL may include the dye, the pigment, or the combination thereof, and the reflection control layer RCL may not include the second layer L2, and a separate layer including the liquid repellent material LRA may be disposed on the reflection control layer RCL.

The protective film PF may be disposed on the reflection control layer RCL. The protective film PF may be disposed relatively outside the display device DD to protect internal configurations of the display device DD.

According to an embodiment, the protective film PF may contact the reflection control layer RCL. In an embodiment, for example, the protective film PF may be physically separated from the first layer L1 and may physically contact the second layer L2.

According to an embodiment, the protective film PF may include one of a polyethyleneterephthalate (PET) film, a low reflection film, a polarizing film, and a transmittance controllable film. However, the disclosure is not limited thereto.

A structure of the outer unit OUP according to an embodiment is not limited to the above-described example. In an embodiment, for example, the outer unit OUP may further include a window configured to transmit light.

Hereinafter, a method of manufacturing the display device DD according to an embodiment will be described with reference to FIGS. 7 to 9. Hereinafter, for convenience of description, any repetitive detailed description of the same or like elements as those described above will be omitted or simplified.

FIGS. 7 to 9 are schematic cross-sectional views for each process step illustrating a method of manufacturing a display device according to an embodiment.

For convenience of description, FIGS. 7 to 9 schematically show a cross-sectional structure of the display device DD during an embodiment of a manufacturing process based on the cross-sectional structure shown in FIG. 6 described above.

Referring to FIG. 7, in an embodiment of a method of manufacturing f the display device DD, the display unit DP may be manufactured first, and then, the sensor unit TSP may be disposed on the display unit DP. In an embodiment, for example, structures related to the display unit DP and the sensor unit TSP may be formed by patterning a conductive layer, an insulating layer, and/or an organic material layer on the display base layer DBSL.

Layers on the display base layer DBSL may be formed based on a typical process for manufacturing a semiconductor device. In an embodiment, for example, the conductive layer or the insulating layer on the display base layer DBSL may be formed by a photolithography process and may be deposited by various methods (sputtering, chemical vapor deposition, and the like). The disclosure is not necessarily limited to a specific example.

In this process, the light blocking layer BM may be disposed on the sensor unit TSP, and a base reflection control layer RCL′ including the liquid repellent material LRA may be disposed on the light blocking layer BM.

In this process, the light blocking layer BM may be selectively patterned in a partial area to define the sub-pixel area SPXA described above.

According to an embodiment, the base reflection control layer RCL′ may be disposed to manufacture the reflection control layer RCL including the first layer L1 and the second layer L2. The base reflection control layer RCL′ may be a layer defined before the liquid repellent material LRA is moved to an outside.

According to an embodiment, the base reflection control layer RCL′ may be disposed by various processing methods. In an embodiment, for example, the base reflection control layer RCL′ may be formed by a photolithography process or may be formed by an inkjet process. However, the disclosure is not limited to a specific example.

In this process, the liquid repellent material LRA in the base reflection control layer RCL′ may be sporadically distributed in the base reflection control layer RCL′. In an embodiment, for example, the liquid repellent material LRA in the base reflection control layer RCL′ may be entirely disposed on inner areas of the base reflection control layer RCL′, and may not be selectively disposed in a partial area.

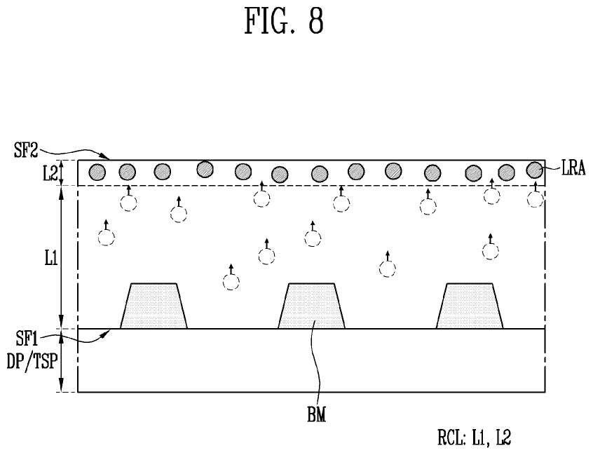

Referring to FIG. 8, the liquid repellent material LRA may be moved to be adjacent to the second surface SF2 that is opposite to the first surface SF1 to which the display unit DP and the sensor unit TSP are adjacent, and thus the reflection control layer RCL may be provided. In this process, an upper surface (for example, the second surface SF2) of the base reflection control layer RCL′ may be exposed.

According to an embodiment, the liquid repellent material LRA may have liquid repellency (or surface energy) greater than the dye, the pigment, or the combination thereof for forming the reflection control layer RCL, and thus the liquid repellent material LRA may be moved to be adjacent to an exposed outer surface (for example, the second surface SF2) of the reflection control layer RCL. Accordingly, the first layer L1 that substantially does not includes the liquid repellent material LRA and the second layer L2 in which the liquid repellent material LRA is distributed in a film shape may be defined (or formed).

As this process is performed, the second layer L2 including the liquid repellent material LRA may be entirely disposed on an upper surface of the first layer L1 on which the dye, the pigment, or the combination thereof is formed.

In an embodiment, a curing process for the reflection control layer RCL may be subsequently performed. According to an embodiment, the curing process for the reflection control layer RCL may be performed after the liquid repellent material LRA is moved adjacent to the second surface SF2.

According to an embodiment, the curing process may be a thermal curing process, and according to an embodiment, the curing process may be light (for example, ultraviolet (UV)) curing. However, the disclosure is not limited thereto.

In this process, as the curing process is performed, the second layer L2 may be provided to have hardness greater than that of the first layer L1.

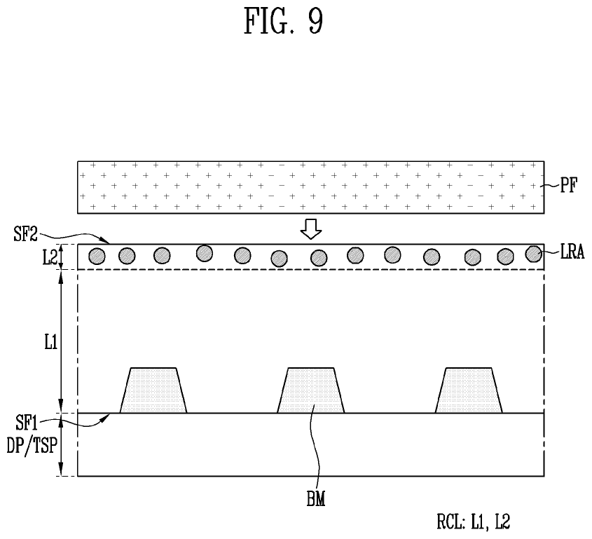

Referring to FIG. 9, the protective film PF may be provided on the reflection control layer RCL.

In this process, the protective film PF may be formed on the reflection control layer RCL and may contact the second layer L2. In an embodiment, for example, the protective film PF may be physically separated from the first layer L1 with the second layer L2 interposed therebetween. Accordingly, a dying of the protective film PF by the first layer L1 may be effectively prevented.

Thereafter, according to an embodiment, the window or the like may be further disposed on the protective film PF, and the display device DD according to an embodiment may be provided.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
sub-pixels corresponding to sub-pixel areas,
wherein each of the sub-pixels comprises:
a display unit including a light-emitting layer which emits light; and
a reflection control layer disposed over the sub-pixel areas on the display unit, wherein the reflection control layer selectively absorbs light in a wavelength band,
wherein the reflection control layer includes a first layer and a second layer disposed on the first layer,
wherein the second layer has a thickness less than a thickness of the first layer, and
wherein the second layer includes a liquid repellent material.

2. The display device according to claim 1, wherein the reflection control layer may absorb light in a non-emission wavelength band different from a wavelength band of the light emitted from the light-emitting layer,
the non-emission wavelength band includes a first non-emission wavelength band and a second non-emission wavelength band,
the wavelength band of the light emitted from the light-emitting layer includes a first wavelength band, a second wavelength band, and a third wavelength band,
the first non-emission wavelength band includes a wavelength band between the third wavelength band and the second wavelength band, and
the second non-emission wavelength band includes a wavelength band between the second wavelength band and the first wavelength band.

3. The display device according to claim 2, wherein the first non-emission wavelength band includes at least a partial band of 460 nm to 520 nm,
the second non-emission wavelength band includes at least a partial band of 560 nm to 620 nm,
the first wavelength band is a red wavelength band,
the second wavelength band is a green wavelength band, and
the third wavelength band is a blue wavelength band.

4. The display device according to claim 1, wherein the reflection control layer includes a dye, a pigment, or a combination thereof.

5. The display device according to claim 4, wherein the reflection control layer includes at least one selected from an oxazine-based compound, a cyanine-based compound, a tetraazoporfin-based compound, and a squarylium-based compound.

6. The display device according to claim 1, wherein the display unit comprises:
a light emitting element including a first electrode, a second electrode, and the light-emitting layer electrically connected between the first electrode and the second electrode; and
a low reflection inorganic layer disposed on the light emitting element.

7. The display device according to claim 6, wherein the second electrode is disposed on the light-emitting layer, and
light reflected by the low reflection inorganic layer and light reflected by the second electrode destructively interfere with each other.

8. The display device according to claim 1, further comprising:
a light blocking layer disposed between the display unit and the reflection control layer,
wherein an opening is defined in the light blocking layer,
wherein the opening and the sub-pixel areas overlap each other in a plan view, and
the reflection control layer contacts the light blocking layer.

9. The display device according to claim 8, wherein the light blocking layer contacts the first layer and spaced apart from the second layer.

10. The display device according to claim 1, wherein the liquid repellent material has a liquid repellency greater than a liquid repellency of a dye, a pigment, or a combination thereof included in the reflection control layer.

11. The display device according to claim 1, wherein the liquid repellent material has a surface energy greater than a surface energy of a dye, a pigment, or a combination thereof included in the reflection control layer.

12. The display device according to claim 1, wherein the second layer has a structure of a film shape on the first layer.

13. The display device according to claim 1, wherein the second layer has a hardness greater than a hardness of the first layer.

14. The display device according to claim 1, wherein in the second layer, the liquid repellent material is included at a concentration of 500 ppm or less.

15. The display device according to claim 1, further comprising:
a protective film disposed on the reflection control layer,
wherein the protective film contacts the second layer and is spaced apart from the first layer.

16. A display device comprising:
a display unit; and
a reflection control layer disposed on the display unit, wherein the reflection control layer selectively absorbs light in a wavelength band, and includes a first surface facing the display unit and a second surface opposite to the first surface,
wherein the reflection control layer includes a first layer adjacent to the first surface and a second layer disposed on the first layer and adjacent to the second surface, and
the second layer has a hardness greater than a hardness of the first layer.

17. A method of manufacturing a display device, the method comprising:
providing a display unit; and
providing a base reflection control layer including a dye and a liquid repellent material on the display unit,
wherein the base reflection control layer includes a first surface adjacent to the display unit and a second surface opposite to the first surface, and
wherein in the providing the base reflection control layer on the display unit, the liquid repellent material is moved to be adjacent to the second surface.

18. The method according to claim 17, wherein in the providing the base reflection control layer on the display unit, a reflection control layer including a first layer and a second layer disposed on the first layer and including the liquid repellent material is provided based on the base reflection control layer,
the method further comprises curing the reflection control layer, and
after the curing, the second layer has a hardness greater than a hardness of the first layer.

19. The method according to claim 17, wherein in the providing the) base reflection control layer on the display unit, the second surface of the base reflection control layer is exposed.

20. The method according to claim 18, further comprising:
disposing a protective film on the reflection control layer,
wherein the protective film is spaced apart from the first layer and contacts the second layer.
